(19) United States
(12) Patent Application Publication
(10) Pub. No.: US 2016/0027899 A1
(43) Pub. Date: Jan. 28, 2016

(54) Semiconductor Device and Method of Manufacturing the Same

(71) Applicant: Dongbu Hitek Co., Ltd., Seoul (KR)

(72) Inventors: Dong Seok KIM, Gyeonggi-do (KR); Jeong Gwan LEE, Gyeonggi-do (KR)

(21) Appl. No.: 14/802,809

(22) Filed: Jul. 17, 2015

(30) Foreign Application Priority Data
Jul. 24, 2014 (KR) 10-2014-0093925

(51) Int. Cl. H01L 29/66; H01L 29/423; H01L 21/265; H01L 21/8234; H01L 27/088; H01L 29/78; H01L 21/02

(52) U.S. Cl. CPC H01L 29/66681; H01L 29/7835; H01L 29/42364; H01L 29/66659; H01L 21/02255; H01L 21/0223; H01L 21/823462; H01L 29/66545; H01L 29/66575; H01L 29/7816; H01L 27/088; H01L 21/265

(57) ABSTRACT

A semiconductor device and a method of manufacturing the same are disclosed. The semiconductor device includes a substrate and a MOS transistor formed on the substrate. The MOS transistor includes a first gate insulating layer formed on the substrate, a second gate insulating layer formed on one side of the first gate insulating layer and having a thickness thicker than that of the first gate insulating layer, a gate electrode formed on the first gate insulating layer and the second gate insulating layer, a source region adjacent to the first gate insulating layer, and a drain region adjacent to the second gate insulating layer.

### CROSS-REFERENCE TO RELATED APPLICATION

This application claims the benefit of Korean Patent Application No. 10-2014-0093925, filed on Jul. 24, 2014 and all the benefits accruing therefrom under 35 U.S.C. §119, the contents of which are incorporated by reference in their entirety.

### BACKGROUND

The present disclosure relates to a semiconductor device and a method of manufacturing the same, and more particularly, to a semiconductor device including a MOS transistor and a method of manufacturing the same.

Generally, a semiconductor device such as a radio frequency (RF) device may include a MOS transistor.

The MOS transistor may have a lightly doped drain (LDD) structure to improve short channel effects caused by channel length reduction. Further, the MOS transistor may have a double diffused drain (DDD) structure to prevent a punch-through phenomenon caused by the LDD structure and to improve a breakdown voltage.

When the RF device includes the MOS transistor having the DDD structure, the breakdown voltage of the RF device may be improved. However, the cutoff frequency of the RF device may be reduced by a parasitic capacitance between a gate electrode and a low concentration impurity diffusion region.

### SUMMARY

The present disclosure provides a semiconductor device having improved breakdown voltage and cutoff frequency and a method of manufacturing the same.

In accordance with an aspect of the claimed invention, a semiconductor device may include a substrate and a MOS transistor formed on the substrate. The MOS transistor may include a first gate insulating layer formed on the substrate, a second gate insulating layer formed on one side of the first gate insulating layer and having a thickness thicker than that of the first gate insulating layer, a gate electrode formed on the first gate insulating layer and the second gate insulating layer, a source region adjacent to the first gate insulating layer, and a drain region adjacent to the second gate insulating layer.

In accordance with some exemplary embodiments, the source region may have a lightly doped drain (LDD) structure.

In accordance with some exemplary embodiments, the drain region may have a double diffused drain (DDD) structure.

In accordance with some exemplary embodiments, the MOS transistor may be formed on a low voltage region of the substrate, and a high voltage MOS transistor including a high voltage gate insulating layer thicker than the second gate insulating layer may be formed on a high voltage region of the substrate.

In accordance with some exemplary embodiments, the MOS transistor may be formed on a high voltage region of the substrate, and a low voltage MOS transistor comprising a low voltage gate insulating layer thinner than the first gate insulating layer may be formed on a low voltage region of the substrate.

In accordance with some exemplary embodiments, the low voltage gate insulating layer may include a third gate insulating layer and a fourth gate insulating layer. Particularly, the fourth gate insulating layer may be formed on one side of the third gate insulating layer and have a thickness thicker than that of the third gate insulating layer and thinner than that of the first gate insulating layer. At this time, a low voltage gate electrode may be formed on the third and fourth gate insulating layers.

In accordance with another aspect of the claimed invention, a method of manufacturing a semiconductor device may include forming a first gate insulating layer and a second gate insulating layer on a substrate. The second gate insulating layer may be disposed on one side of the first gate insulating layer and have a thickness thicker than that of the first gate insulating layer. Further, the method may include forming a gate electrode on the first gate insulating layer and the second gate insulating layer and forming a source region and a drain region at surface portions of the substrate adjacent to the first gate insulating layer and the second gate insulating layer, respectively.

In accordance with some exemplary embodiments, the first gate insulating layer and the second gate insulating layer may be formed on a low voltage region of the substrate.

In accordance with some exemplary embodiments, a preliminary gate insulating layer may be formed on the low voltage region and a high voltage region of the substrate.

In accordance with some exemplary embodiments, the forming the first gate insulating layer and the second gate insulating layer may include implanting fluorine ions into a region on which the second gate insulating layer will be formed and performing a thermal oxidation process so as to form the first gate insulating layer and the second gate insulating layer.

In accordance with some exemplary embodiments, a portion of the preliminary gate insulating layer on the low voltage region may be removed before performing the thermal oxidation process.

In accordance with some exemplary embodiments, a high voltage gate insulating layer thicker than the second gate insulating layer may be formed on the high voltage region by the thermal oxidation process.

In accordance with some exemplary embodiments, the source region may have a lightly doped drain (LDD) structure.

In accordance with some exemplary embodiments, the drain region may have a double diffused drain (DDD) structure.

In accordance with some exemplary embodiments, the first gate insulating layer and the second gate insulating layer may be formed on a high voltage region of the substrate.

In accordance with some exemplary embodiments, the forming the first gate insulating layer and the second gate insulating layer may include implanting fluorine ions into a region on which the second gate insulating layer will be formed, performing a first thermal oxidation process so as to form a first preliminary gate insulating layer and a second preliminary gate insulating layer thicker than that of the first preliminary gate insulating layer, and performing a second thermal oxidation process so as to form the first gate insulating layer and the second gate insulating layer.

In accordance with some exemplary embodiments, a portion of the first preliminary gate insulating layer formed on a low voltage region of the substrate by the first thermal oxidation process may be removed before performing the second thermal oxidation process.

In accordance with some exemplary embodiments, a low voltage gate insulating layer thinner than the first gate insulating layer may be formed on the low voltage region by the second thermal oxidation process.

In accordance with some exemplary embodiments, the method may further include implanting fluorine ions into a portion of the low voltage region before removing the portion of the first preliminary gate insulating layer.

In accordance with some exemplary embodiments, a third gate insulating layer and a fourth gate insulating layer thicker than the third gate insulating layer may be formed on the low voltage region by the second thermal oxidation process. Particularly, the fourth gate insulating layer may be formed on the portion of the low voltage region and have a thickness thinner than that of the first gate insulating layer.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a semiconductor device in accordance with an exemplary embodiment of the claimed invention;

FIGS. 2 to 4 are cross-sectional views illustrating semiconductor devices in accordance with other exemplary embodiments of the claimed invention;

FIGS. 5 to 10 are cross-sectional views illustrating a method of manufacturing the semiconductor device as shown in FIG. 1;

FIGS. 11 to 17 are cross-sectional views illustrating a method of manufacturing the semiconductor device as shown in FIG. 2;

FIGS. 18 to 25 are cross-sectional views illustrating a method of manufacturing the semiconductor device as shown in FIG. 3; and

FIGS. 26 to 31 are cross-sectional views illustrating a method of manufacturing the semiconductor device as shown in FIG. 4.

While embodiments are amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF EMBODIMENTS

Hereinafter, specific embodiments will be described in more detail with reference to the accompanying drawings. The claimed invention may, however, be embodied in different forms and should not be construed as limited to the embodiments set forth herein. Rather, these embodiments are provided so that this disclosure will be thorough and complete, and will fully convey the scope of the claimed invention to those skilled in the art.

It will also be understood that when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the claimed invention are not limited to these terms.

In the following description, the technical terms are used only for explaining specific embodiments while not limiting the claimed invention. Unless otherwise defined herein, all the terms used herein, which include technical or scientific terms, may have the same meaning that is generally understood by those skilled in the art. In general, the terms defined in the dictionary should be considered to have the same meaning as the contextual meaning of the related art, and, unless clearly defined herein, should not be understood as abnormally or excessively formal meaning.

The embodiments of the claimed invention are described with reference to schematic diagrams of ideal embodiments of the claimed invention. Accordingly, changes in the shapes of the diagrams, for example, changes in manufacturing techniques and/or allowable errors, are sufficiently expected. Accordingly, embodiments of the claimed invention are not described as being limited to specific shapes of areas described with diagrams and include deviations in the shapes and also the areas described with drawings are entirely schematic and their shapes do not represent accurate shapes and also do not limit the scope of the claimed invention.

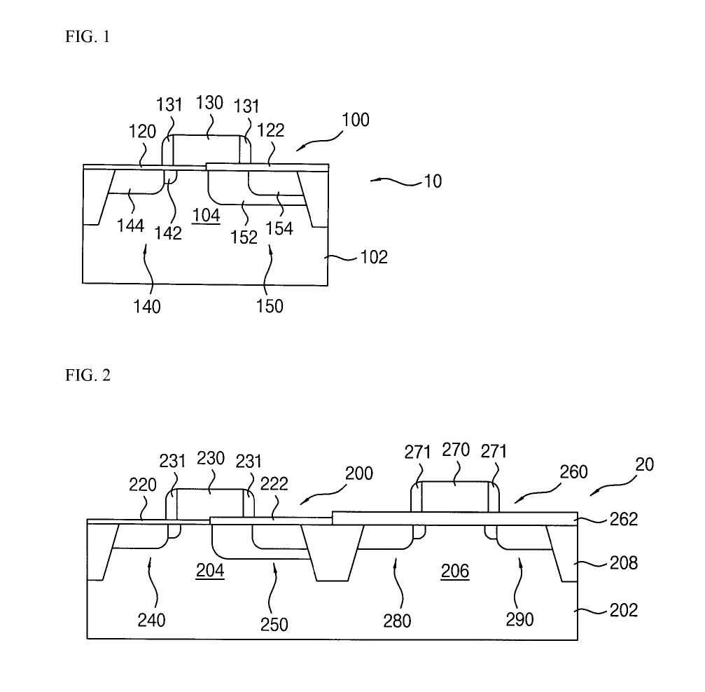

FIG. 1 is a cross-sectional view illustrating a semiconductor device in accordance with an exemplary embodiment of the claimed invention.

Referring to FIG. 1, a semiconductor device 10, in accordance with an exemplary embodiment of the claimed invention, may include a substrate 102 such as a silicon wafer and a MOS transistor 100 formed on the substrate 102.

The MOS transistor 100 may include a first gate insulating layer 120 formed on an active region 104 of the substrate 102, a second gate insulating layer 122 formed on one side of the first gate insulating layer 120 and having a thickness thicker than that of the first gate insulating layer 120, a gate electrode 130 formed on the first gate insulating layer 120 and the second gate insulating layer 122, a source region 140 formed at a surface portion of the substrate 102 adjacent to the first gate insulating layer 120, and a drain region 150 formed at a surface portion of the substrate 102 adjacent to the second gate insulating layer 122.

For example, the source region 140 may have a lightly doped drain (LDD) structure, and the drain region 150 may have a double diffused drain (DDD) structure in order to improve a breakdown voltage of the semiconductor device 10.

The source region 140 may include a low concentration impurity region 142 and a high concentration impurity region 144, and the drain region 150 may include a low concentration impurity diffusion region 152 and a high concentration impurity diffusion region 154. Particularly, the second gate insulating layer 122 may have a thickness thicker than that of the first gate insulating layer 120, and a parasitic capacitance may thus be reduced between the gate electrode 130 and the low concentration impurity diffusion region 152. As a result, a cutoff frequency of the semiconductor device 10 may be sufficiently improved.

FIGS. 2 to 4 are cross-sectional views illustrating semiconductor devices in accordance with other exemplary embodiments of the claimed invention.

Referring to FIG. 2, a semiconductor device 20 may include a low voltage MOS transistor 200 configured for use at a relatively low voltage and a high voltage MOS transistor 260 configured for use at a relatively high voltage. For example, the low voltage may be between about 0.1 and about 3, and the high voltage may be between about 3 and about 6. More particularly, the low voltage may be between about 1 and about 2, and the high voltage may be between about 3 and about 4.

The low voltage MOS transistor 200 may include a first gate insulating layer 220 formed on a low voltage region 204 of a substrate 202, a second gate insulating layer 222 formed on one side of the first gate insulating layer 220 and having a thickness thicker than that of the first gate insulating layer 220, a gate electrode 230 formed on the first gate insulating layer 220 and the second gate insulating layer 222, a source region 240 formed at a surface portion of the low voltage region 204 adjacent to the first gate insulating layer 220, and a drain region 250 formed at a surface portion of the low voltage region 204 adjacent to the second gate insulating layer 222. For example, the source region 240 and the drain region 250 of the low voltage MOS transistor 200 may have an LDD structure and a DDD structure, respectively.

The high voltage MOS transistor 260 may include a high voltage gate insulating layer 262 formed on a high voltage region 206 of the substrate 202, a high voltage gate electrode 270 formed on the high voltage gate insulating layer 262 and source/drain regions 280 and 290 disposed on both sides of the high voltage gate electrode 270. For example, the source/drain regions 280 and 290 may have an LDD structure, and the high voltage gate insulating layer 262 may have a thickness thicker than that of the second gate insulating layer 222.

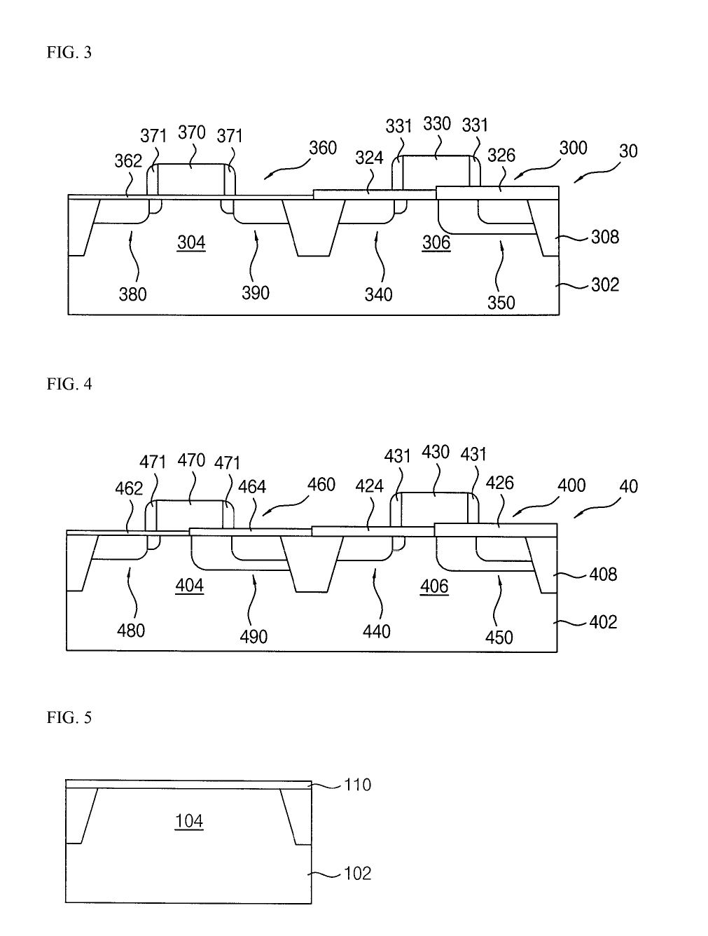

Referring to FIG. 3, a semiconductor device 30 may include a high voltage MOS transistor 300 configured for use at a relatively high voltage and a low voltage MOS transistor 360 configured for use at a relatively low voltage. For example, the low voltage may be between about 0.1 and about 3, and the high voltage may be between about 3 and about 6. More particularly, the low voltage may be between about 1 and about 2, and the high voltage may be between about 3 and about 4.

The high voltage MOS transistor 300 may include a first gate insulating layer 324 formed on a high voltage region 306 of a substrate 302, a second gate insulating layer 326 formed on one side of the first gate insulating layer 324 and having a thickness thicker than that of the first gate insulating layer 324, a gate electrode 330 formed on the first gate insulating layer 324 and the second gate insulating layer 326, a source region 340 formed at a surface portion of the high voltage region 306 adjacent to the first gate insulating layer 324, and a drain region 350 formed at a surface portion of the high voltage region 306 adjacent to the second gate insulating layer 326. For example, the source region 340 and the drain region 350 of the high voltage MOS transistor 300 may have an LDD structure and a DDD structure, respectively.

The low voltage MOS transistor 360 may include a low voltage gate insulating layer 362 formed on a low voltage region 304 of the substrate 302, a low voltage gate electrode 370 formed on the low voltage gate insulating layer 362 and source/drain regions 380 and 390 disposed on both sides of the low voltage gate electrode 370. For example, the source/drain regions 380 and 390 may have an LDD structure, and the low voltage gate insulating layer 362 may have a thickness thinner than that of the first gate insulating layer 324.

Referring to FIG. 4, a semiconductor device 40 may include a high voltage MOS transistor 400 configured for use at a relatively high voltage and a low voltage MOS transistor 460 configured for use at a relatively low voltage. For example, the low voltage may be between about 0.1 and about 3, and the high voltage may be between about 3 and about 6. More particularly, the low voltage may be between about 1 and about 2, and the high voltage may be between about 3 and about 4.

The high voltage MOS transistor 400 may include a first gate insulating layer 424 formed on a high voltage region 406 of a substrate 402, a second gate insulating layer 426 formed on one side of the first gate insulating layer 424 and having a thickness thicker than that of the first gate insulating layer 424, a gate electrode 430 formed on the first gate insulating layer 424 and the second gate insulating layer 426, a source region 440 formed at a surface portion of the high voltage region 406 adjacent to the first gate insulating layer 424, and a drain region 450 formed at a surface portion of the high voltage region 406 adjacent to the second gate insulating layer 426. For example, the source region 440 and the drain region 450 of the high voltage MOS transistor 400 may have an LDD structure and a DDD structure, respectively.

The low voltage MOS transistor 460 may include a third gate insulating layer 462 formed on a low voltage region 404 of the substrate 402, a fourth gate insulating layer 464 formed on one side of the third gate insulating layer 462 and having a thickness thicker than that of the third gate insulating layer 462, a gate electrode 470 formed on the third gate insulating layer 462 and the fourth gate insulating layer 464, a source region 480 formed at a surface portion of the low voltage region 404 adjacent to the third gate insulating layer 462, and a drain region 490 formed at a surface portion of the low voltage region 404 adjacent to the fourth gate insulating layer 464. For example, the source region 480 and the drain region 490 of the low voltage MOS transistor 460 may have an LDD structure and a DDD structure, respectively. Further, the fourth gate insulating layer 464 may have a thickness thinner than that of the first gate insulating layer 424.

FIGS. 5 to 10 are cross-sectional views illustrating a method of manufacturing the semiconductor device as shown in FIG. 1

Referring to FIG. 5, a pad oxide layer 110 may be formed on an active region 104 of a substrate 102. For example, the pad oxide layer 110 may be formed by a thermal oxidation process or a chemical vapor deposition (CVD) process.

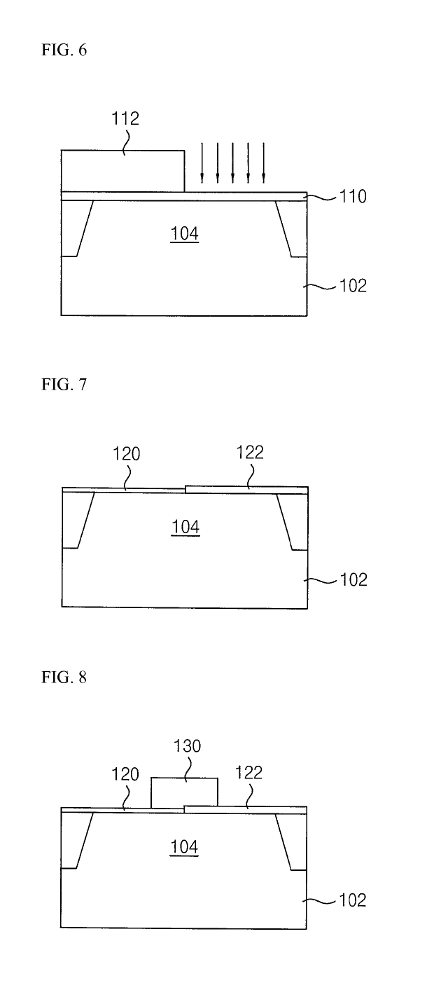

Referring to FIG. 6, the active region 110 may include a first region on which a first gate insulating layer 120 (See FIG. 7) will be formed and a second region on which a second gate insulating layer 122 (See FIG. 7) will be formed. A photoresist pattern 112 having an opening exposing the second region may be formed on the pad oxide layer 110.

Then, an ion implantation process using the photoresist pattern 112 as an ion implantation mask may be performed in order to implant fluorine ions into a surface portion of the second region. The fluorine ions may increase an oxide growth rate during a subsequent thermal oxidation process. The photoresist pattern 112 may be removed by ashing and/or strip process after performing the ion implantation process, and the pad oxide layer 110 may be removed by a wet etching process using a HF (hydrofluoric acid) solution or a SC1 (standard cleaning 1) solution.

Referring to FIG. 7, a thermal oxidation process may be performed in order to form the first gate insulating layer 120 on the first region of the active region 104 and the second gate insulating layer 122 having a thickness thicker than that of the first gate insulating layer 120 on the second region of the active region 104.

Referring to FIG. 8, a gate electrode 130 may be formed on the first gate insulating layer 120 and the second gate insulating layer 122. For example, a gate polysilicon layer may be formed by a CVD process, and the gate polysilicon layer may then be patterned by an anisotropic etching process so as to form the gate electrode 130.

Referring to FIG. 9, a low concentration impurity diffusion region 152 may be formed at a surface portion of the active region 104 adjacent to the second gate insulating layer 122, and a low concentration impurity region 142 may be formed at a surface portion of the active region 104 adjacent to the first gate insulating layer 120.

For example, a photoresist pattern (not shown) exposing a drain region adjacent to the second gate insulating layer 122 may be formed, and an ion implantation process using n-type dopants such as arsenic and phosphorus may then be performed to form a low concentration impurity region at a surface portion of the drain region. The n-type dopants implanted into the surface portion of the drain region may be diffused by an annealing process thereby forming the low concentration impurity diffusion region 152.

Further, a photoresist pattern (not shown) exposing a source region adjacent to the first gate insulating layer 120 may be formed, and an ion implantation process using n-type dopants may then be performed to form the low concentration impurity region 142 at a surface portion of the source region.

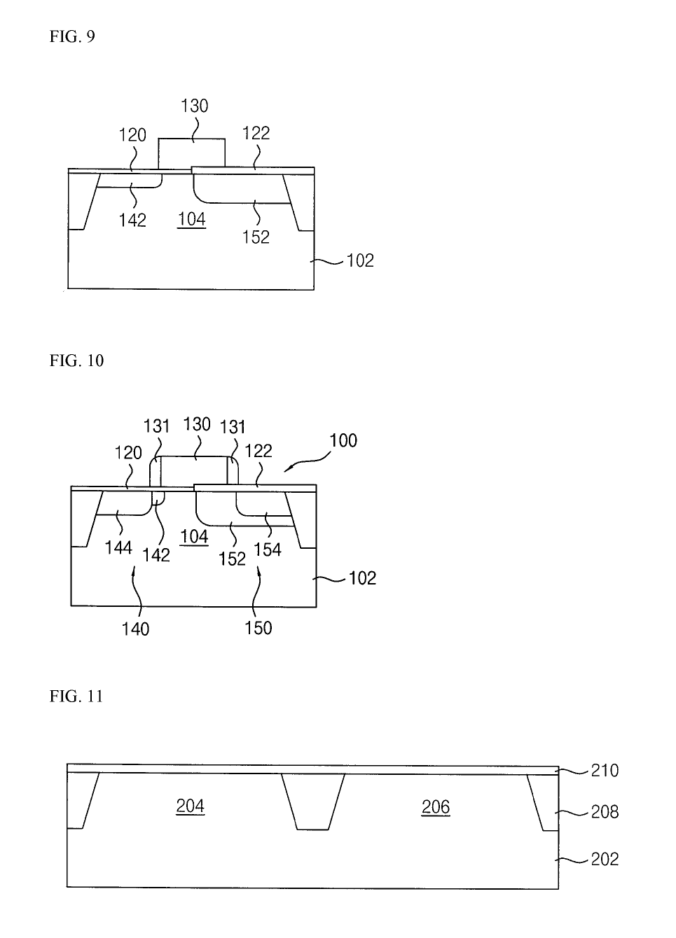

Referring to FIG. 10, spacers 131 may be formed on side surfaces of the gate electrode 130, and a high concentration impurity region 144 and a high concentration impurity diffusion region 154 may then be formed at surface portions of the source region and the drain region, respectively.

For example, the high concentration impurity region 144 and the high concentration impurity diffusion region 154 may be formed by an ion implantation process using n-type dopants. As a result, a MOS transistor 100 including a source region 140 of an LDD structure and a drain region 150 of a DDD structure may be formed on the substrate 102.

FIGS. 11 to 17 are cross-sectional views illustrating a method of manufacturing the semiconductor device as shown in FIG. 2.

Referring to FIG. 11, a preliminary gate insulating layer 210 may be formed on a low voltage region 204 and a high voltage region 206 of a substrate 202. The preliminary gate insulating layer 210 may be formed by a thermal oxidation process, and the low voltage region 204 and the high voltage region 206 may be electrically isolated from each other by a device isolation region 208 formed by a STI (Shallow Trench Isolation) process.

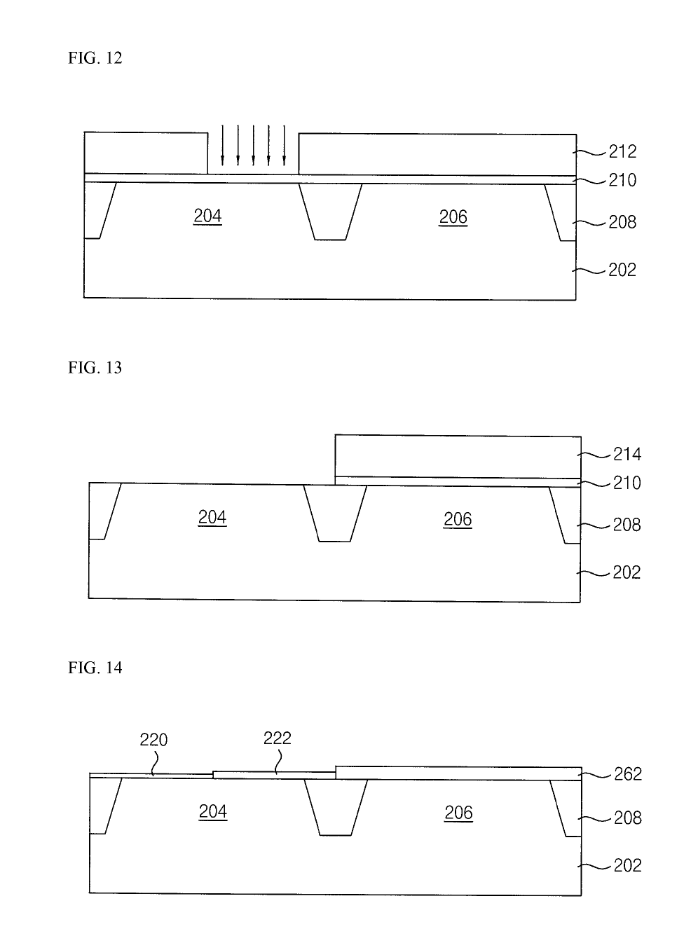

Referring to FIG. 12, the low voltage region 204 may include a first region on which a first gate insulating layer 220 (See FIG. 14) will be formed and a second region on which a second gate insulating layer 222 (See FIG. 14) will be formed. A photoresist pattern 212 having an opening exposing the second region may be formed on the preliminary gate insulating layer 210.

Then, an ion implantation process using the photoresist pattern 212 as an ion implantation mask may be performed in order to implant fluorine ions into a surface portion of the second region. The fluorine ions may increase an oxide growth rate during a subsequent thermal oxidation process. The photoresist pattern 212 may be removed by ashing and/or strip process after performing the ion implantation process.

Referring to FIG. 13, a photoresist pattern 214 exposing the low voltage region 204 may be formed on the preliminary gate insulating layer 210, and a portion of the preliminary gate insulating layer 210 on the low voltage region 204 may be removed. For example, the portion of the preliminary gate insulating layer 210 on the low voltage region 204 may be removed by a wet etching process using a HF solution or a SC1 solution.

The photoresist pattern 214 may be removed by ashing and/or strip process after removing the portion of the preliminary gate insulating layer 210 on the low voltage region 204.

Referring to FIG. 14, a thermal oxidation process may be performed to form a first gate insulating layer 220 on the first region of the low voltage region 204 and a second gate insulating layer 222 having a thickness thicker than that of the first gate insulating layer 220 on the second region of the low voltage region 204. Further, a high voltage gate insulating layer 262 having a thickness thicker than that of the second gate insulating layer 222 may be formed on the high voltage region 206 by the thermal oxidation process.

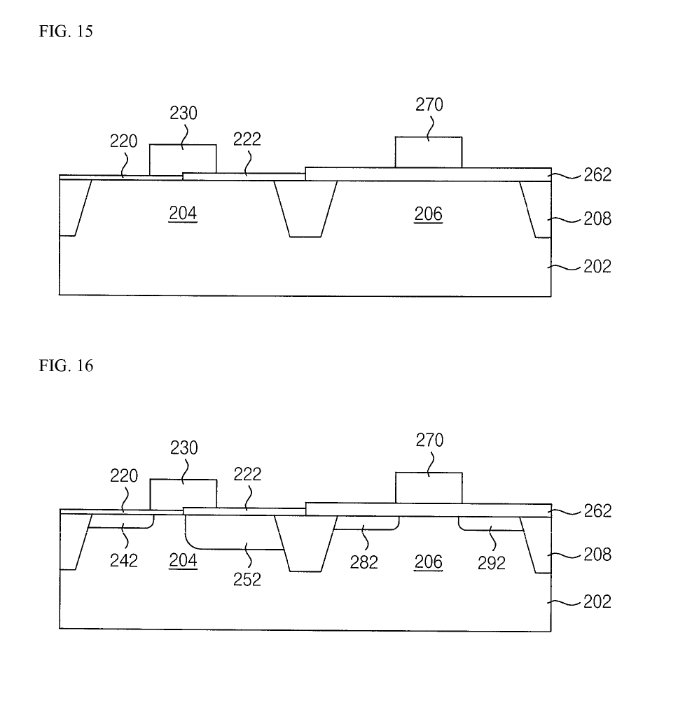

Referring to FIG. 15, a gate electrode 230 may be formed on the first gate insulating layer 220 and the second gate insulating layer 222, and a high voltage gate electrode 270 may be formed on the high voltage gate insulating layer 262. For example, a gate polysilicon layer may be formed by a CVD process, and the gate polysilicon layer may then be patterned by an anisotropic etching process so as to form the gate electrode 230 and the high voltage gate electrode 270.

Referring to FIG. 16, a low concentration impurity diffusion region 252 may be formed at a surface portion of the low voltage region 204 adjacent to the second gate insulating layer 222, and a low concentration impurity region 242 may be formed at a surface portion of the low voltage region 204 adjacent to the first gate insulating layer 220. Further, low concentration impurity regions 282 and 292 may be formed at surface portions of the high voltage region 206 adjacent to the high voltage gate electrode 270.

For example, a photoresist pattern (not shown) may be formed to expose a drain region adjacent to the second gate insulating layer 222, and an ion implantation process using n-type dopants may then be performed to form a low concentration impurity region at a surface portion of the drain region. The n-type dopants implanted into the surface portion of the drain region may be diffused by an annealing process thereby forming the low concentration impurity diffusion region 252.

Further, a photoresist pattern (not shown) may be formed to expose a source region adjacent to the first gate insulating layer 220 and source/drain regions adjacent to the high voltage gate electrode 270, and an ion implantation process using n-type dopants may then be performed to form the low concentration impurity regions 242, 282 and 292.

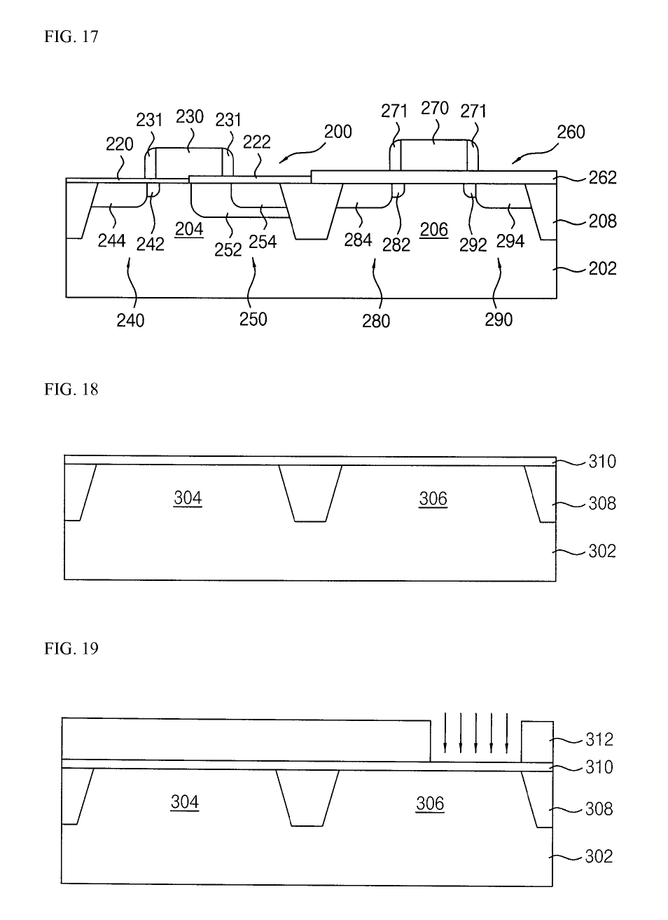

Referring to FIG. 17, spacers 231 may be formed on side surfaces of the gate electrode 230, and spacers 271 may be formed on the side surfaces of the high voltage gate electrode 270. Then, a high concentration impurity region 244 and a high concentration impurity diffusion region 254 may be formed at surface portions of the source region and the drain region, respectively. Further, high concentration impurity regions 284 and 294 may be formed at surface portions of the source/drain regions.

For example, the high concentration impurity regions 244, 284 and 294 and the high concentration impurity diffusion region 254 may be formed by an ion implantation process using n-type dopants. As a result, a low voltage MOS transistor 200 including a source region 240 of an LDD structure and a drain region 250 of a DDD structure and a high voltage MOS transistor 260 including source/drain regions 280 and 290 of an LDD structure may be formed on the substrate 202.

FIGS. 18 to 25 are cross-sectional views illustrating a method of manufacturing the semiconductor device as shown in FIG. 3.

Referring to FIG. 18, a pad oxide layer 310 may be formed on a low voltage region 304 and a high voltage region 306 of a substrate 302. The pad oxide layer 310 may be formed by a thermal oxidation process or a CVD process, and the low voltage region 304 and the high voltage region 306 may be electrically isolated from each other by a device isolation region 308 formed by a STI (Shallow Trench Isolation) process.

Referring to FIG. 19, the high voltage region 306 may include a first region on which a first gate insulating layer 324 (See FIG. 22) will be formed and a second region on which a second gate insulating layer 326 (See FIG. 22) will be formed. A photoresist pattern 312 having an opening exposing the second region may be formed on the pad oxide layer 310.

Then, an ion implantation process using the photoresist pattern 312 as an ion implantation mask may be performed in order to implant fluorine ions into a surface portion of the second region. The fluorine ions may increase an oxide growth rate during a subsequent first thermal oxidation process. The photoresist pattern 312 may be removed by ashing and/or strip process after performing the ion implantation process, and the pad oxide layer 310 may be removed by a wet etching process using a HF solution or a SC1 solution.

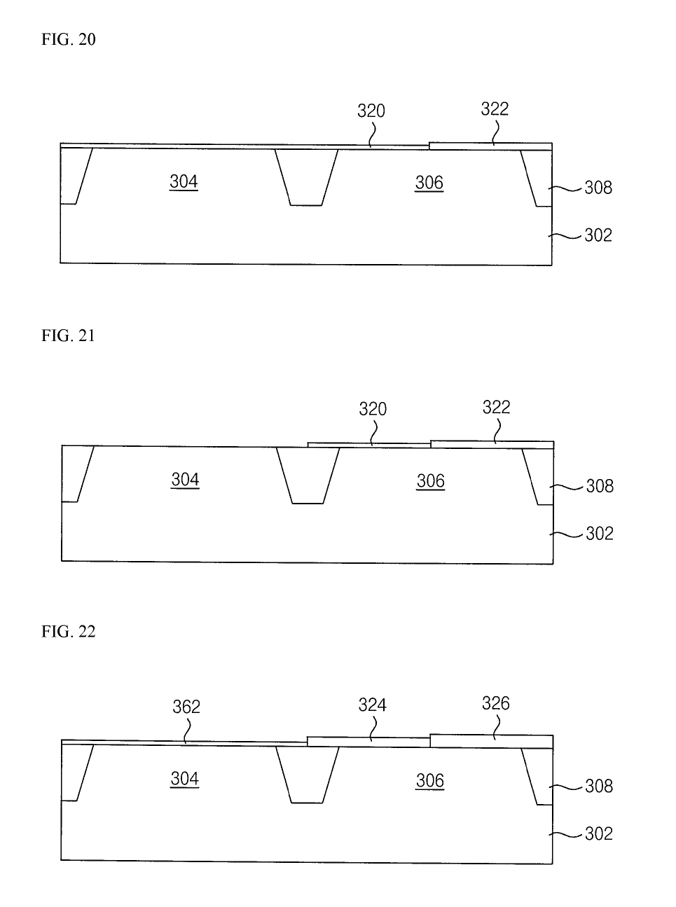

Referring to FIG. 20, a first thermal oxidation process may be performed to form a first preliminary gate insulating layer 320 on the low voltage region 304 and the first region of the high voltage region 306 and a second preliminary gate insulating layer 322 having a thickness thicker than that of the first preliminary gate insulating layer 320 on the second region of the high voltage region 306.

Referring to FIG. 21, a photoresist pattern (not shown) exposing the low voltage region 304 may be formed, and a portion of the first preliminary gate insulating layer 320 on the low voltage region 304 may then be removed. For example, the portion of the first preliminary gate insulating layer 320 on the low voltage region 304 may be removed by a wet etching process using a HF solution or a SC1 solution. The photoresist pattern may be removed by ashing and/or strip process after removing the portion of the first preliminary gate insulating layer 320 on the low voltage region 304.

Referring to FIG. 22, a second thermal oxidation process may be performed to form a first gate insulating layer 324 on the first region of the high voltage region 306 and a second gate insulating layer 326 having a thickness thicker than that of the first gate insulating layer 324 on the second region of the high voltage region 306. Further, a low voltage gate insulating layer 362 having a thickness thinner than that of the first gate insulating layer 324 may be formed on the low voltage region 304 by the second thermal oxidation process.

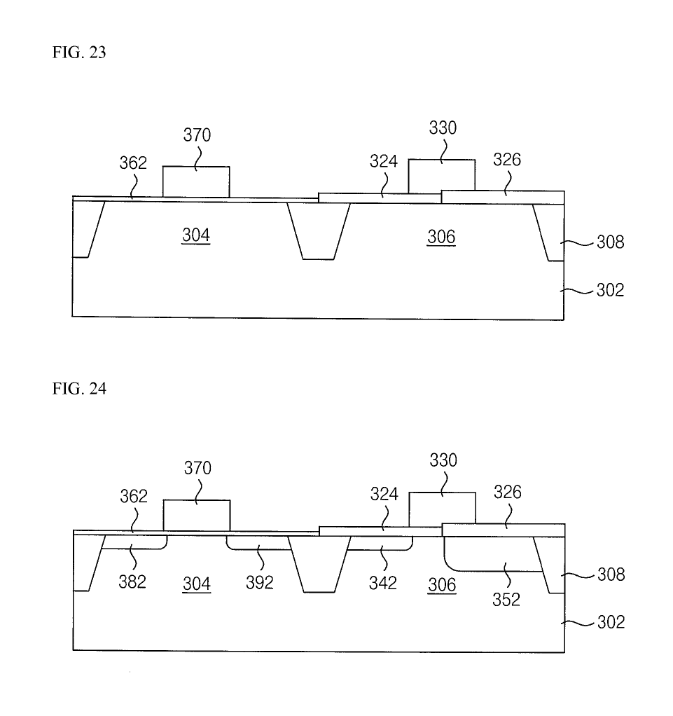

Referring to FIG. 23, a gate electrode 330 may be formed on the first gate insulating layer 324 and the second gate insulating layer 326, and a low voltage gate electrode 370 may be formed on the low voltage gate insulating layer 362. For example, a gate polysilicon layer may be formed by a CVD process, and the gate polysilicon layer may then be patterned by an anisotropic etching process so as to form the gate electrode 330 and the low voltage gate electrode 370.

Referring to FIG. 24, a low concentration impurity diffusion region 352 may be formed at a surface portion of the high voltage region 306 adjacent to the second gate insulating layer 326, and a low concentration impurity region 342 may be formed at a surface portion of the high voltage region 306 adjacent to the first gate insulating layer 324. Further, low concentration impurity regions 382 and 392 may be formed at surface portions of the low voltage region 304 adjacent to the low voltage gate electrode 370.

For example, a photoresist pattern (not shown) may be formed to expose a drain region adjacent to the second gate insulating layer 326, and an ion implantation process using n-type dopants may then be performed to form a low concentration impurity region at a surface portion of the drain region. The n-type dopants implanted into the surface portion of the drain region may be diffused by an annealing process thereby forming the low concentration impurity diffusion region 352.

Further, a photoresist pattern (not shown) may be formed to expose a source region adjacent to the first gate insulating layer 324 and source/drain regions adjacent to the low voltage gate electrode 370, and an ion implantation process using n-type dopants may then be performed to form the low concentration impurity regions 342, 382 and 392.

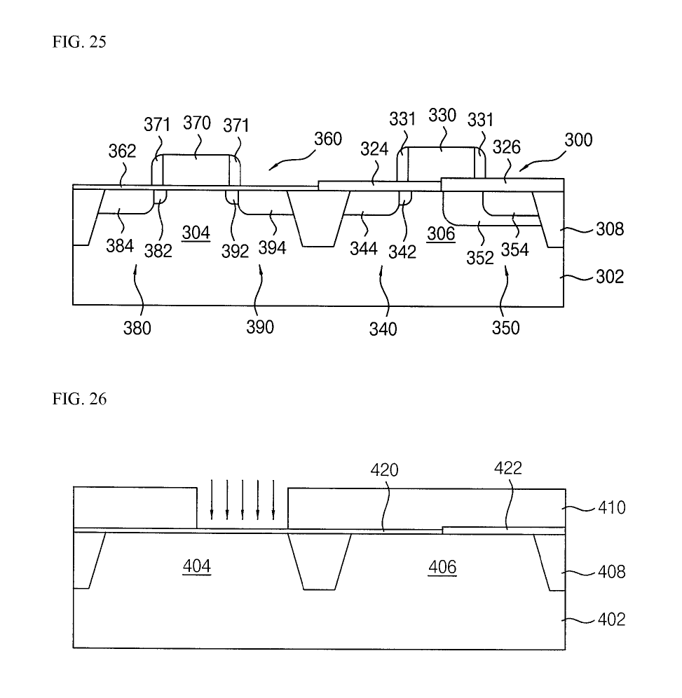

Referring to FIG. 25, spacers 331 may be formed on side surfaces of the gate electrode 330, and spacers 371 may be formed on the side surfaces of the low voltage gate electrode 370. Then, a high concentration impurity region 344 and a high concentration impurity diffusion region 354 may be formed at surface portions of the source region and the drain region, respectively. Further, high concentration impurity regions 384 and 394 may be formed at surface portions of the source/drain regions.

For example, the high concentration impurity regions 344, 384 and 394 and the high concentration impurity diffusion region 354 may be formed by an ion implantation process using n-type dopants. As a result, a high voltage MOS transistor 300 including a source region 340 of an LDD structure and a drain region 350 of a DDD structure and a low voltage MOS transistor 360 including source/drain regions 380 and 390 of an LDD structure may be formed on the substrate 302.

FIGS. 26 to 31 are cross-sectional views illustrating a method of manufacturing the semiconductor device as shown in FIG. 4.

Referring to FIG. 26, a first preliminary gate insulating layer 420 may be formed on a first region of a high voltage region 406 of a substrate 402, and a second preliminary gate insulating layer 422 may be formed on a second region of the high voltage region 406. The first and second preliminary gate insulating layers 420 and 422 may be formed by a first thermal oxidation process. A low voltage region 404 of the substrate 402 and the high voltage region 406 may be electrically isolated from each other by a device isolation region 408.

Steps of forming the first and second preliminary gate insulating layers 420 and 422 are substantially the same as those described in FIGS. 18 to 20, and thus detailed descriptions thereof will be omitted.

The low voltage region 404 of the substrate 402 may include a third region on which a third gate insulating layer 462 (See FIG. 28) will be formed and a fourth region on which a fourth gate insulating layer 464 (See FIG. 28) will be formed.

A photoresist pattern 410 having an opening exposing the fourth region of the low voltage region 404 may be formed on the first and second preliminary gate insulating layers 420 and 422, and an ion implantation process using the photoresist pattern 410 as an ion implantation mask may be performed in order to implant fluorine ions into a surface portion of the fourth region. The fluorine ions may increase an oxide growth rate during a subsequent second thermal oxidation process. The photoresist pattern 410 may be removed by ashing and/or strip process after performing the ion implantation process.

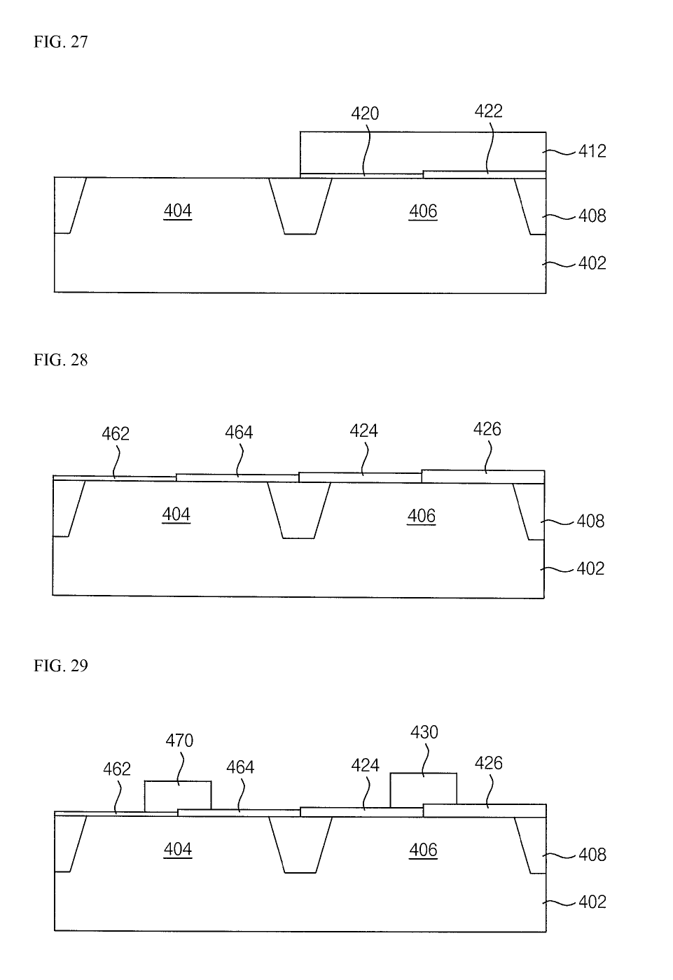

Referring to FIG. 27, a photoresist pattern 412 exposing the low voltage region 404 may be formed on the first and second preliminary gate insulating layers 420 and 422, and a portion of the first preliminary gate insulating layer 420 on the low voltage region 404 may then be removed. For example, the portion of the first preliminary gate insulating layer 420 on the low voltage region 404 may be removed by a wet etching process using a HF solution or a SC1 solution. The photoresist pattern 412 may be removed by ashing and/or strip process after removing the portion of the first preliminary gate insulating layer 420 on the low voltage region 404.

Referring to FIG. 28, a second thermal oxidation process may be performed to form a first gate insulating layer 424 and a second gate insulating layer 426 having a thickness thicker than that of the first gate insulating layer 424 on the high voltage region 406. Further, a third gate insulating layer 462 and a fourth gate insulating layer 464 having a thickness thicker than that of the third gate insulating layer 462 may be formed on the third and fourth regions of the low voltage region 404, respectively, by the second thermal oxidation process. Particularly, the fourth gate insulating layer 464 may have a thickness thinner than that of the first gate insulating layer 424.

Referring to FIG. 29, a high voltage gate electrode 430 may be formed on the first gate insulating layer 424 and the second gate insulating layer 426, and a low voltage gate electrode 470 may be formed on the third gate insulating layer 462 and the fourth gate insulating layer 464. For example, a gate polysilicon layer may be formed by a CVD process, and the gate polysilicon layer may then be patterned by an anisotropic etching process so as to form the high voltage gate electrode 430 and the low voltage gate electrode 470.

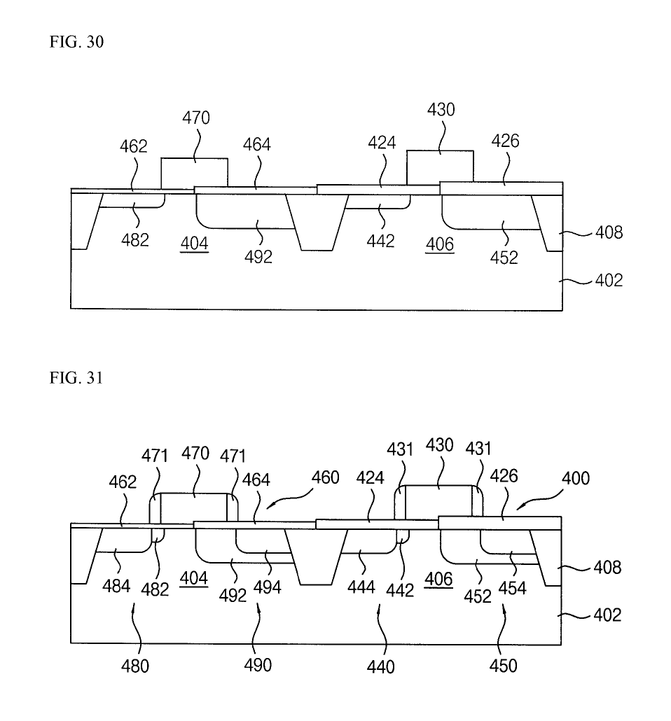

Referring to FIG. 30, a low concentration impurity diffusion region 452 may be formed at a surface portion of the high voltage region 406 adjacent to the second gate insulating layer 426, and a low concentration impurity region 442 may be formed at a surface portion of the high voltage region 406 adjacent to the first gate insulating layer 424. Further, a low concentration impurity diffusion region 492 may be formed at a surface portion of the low voltage region 404 adjacent to the fourth gate insulating layer 464, and a low concentration impurity region 482 may be formed at a surface portion of the low voltage region 404 adjacent to the third gate insulating layer 462.

Referring to FIG. 31, spacers 431 may be formed on side surfaces of the high voltage gate electrode 430, and spacers 471 may be formed on the side surfaces of the low voltage gate electrode 470. Then, high concentration impurity regions 444 and 484 may be formed at surface portions of source regions adjacent to the high voltage gate electrode 430 and the low voltage gate electrode 470. Further, high concentration impurity diffusion regions 454 and 494 may be formed at surface portions of drain regions adjacent to the high voltage gate electrode 430 and the low voltage gate electrode 470. As a result, a high voltage MOS transistor 400 including a source region 440 of an LDD structure and a drain region 450 of a DDD structure and a low voltage MOS transistor 460 including a source region 480 of an LDD structure and a drain region 490 of a DDD structure may be formed on the substrate 302.

In accordance with the above-mentioned embodiments of the claimed invention, a semiconductor device including a MOS transistor may be formed on a substrate. The MOS transistor may include a first gate insulating layer adjacent to a source region, a second gate insulating layer adjacent to a drain region, and a gate electrode formed on the first and second gate insulating layers.

The MOS transistor may have an asymmetric structure. For example, the source region may have an LDD structure, and the drain region may have a DDD structure. Thus, the breakdown voltage of the semiconductor device including the MOS transistor may be sufficiently improved.

Particularly, the second gate insulating layer may have a thickness thicker than that of the first gate insulating layer. Thus, a parasitic capacitance between the gate electrode and a low concentration impurity diffusion region of the drain region may be sufficiently reduced, and further the cutoff frequency of the semiconductor device may be sufficiently improved.

Although a semiconductor device and the method of manufacturing the same have been described with reference to the specific embodiments, they are not limited thereto. Therefore, it will be readily understood by those skilled in the art that various modifications and changes can be made thereto without departing from the spirit and scope of the appended claims.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A semiconductor device comprising:
a substrate; and
a MOS transistor formed on the substrate,
wherein the MOS transistor comprises:
a first gate insulating layer formed on the substrate;
a second gate insulating layer formed on one side of the first gate insulating layer and having a thickness thicker than that of the first gate insulating layer;
a gate electrode formed on the first gate insulating layer and the second gate insulating layer;
a source region adjacent to the first gate insulating layer; and
a drain region adjacent to the second gate insulating layer.

2. The semiconductor device of claim 1, wherein the source region has a lightly doped drain (LDD) structure.

3. The semiconductor device of claim 1, wherein the drain region has a double diffused drain (DDD) structure.

4. The semiconductor device of claim 1, wherein the MOS transistor is formed on a low voltage region of the substrate configured for use at a first, relatively lower voltage, and a high voltage MOS transistor comprising a high voltage gate insulating layer thicker than the second gate insulating layer is formed on a high voltage region of the substrate configured for use at a second, relatively higher voltage.

5. The semiconductor device of claim 1, wherein the MOS transistor is formed on a high voltage region of the substrate configured for use at a second, relatively higher voltage, and a low voltage MOS transistor comprising a low voltage gate insulating layer thinner than the first gate insulating layer is formed on a low voltage region of the substrate configured for use at a first, relatively lower voltage.

6. The semiconductor device of claim 5, wherein the low voltage gate insulating layer comprises a third gate insulating layer and a fourth gate insulating layer, and the fourth gate insulating layer is formed on one side of the third gate insulating layer and has a thickness thicker than a thickness of the third gate insulating layer and thinner than a thickness of the first gate insulating layer.

7. A method of manufacturing a semiconductor device, the method comprising:
forming a first gate insulating layer and a second gate insulating layer on a substrate, the second gate insulating layer being disposed on one side of the first gate insulating layer and having a thickness thicker than a thickness of the first gate insulating layer;
forming a gate electrode on the first gate insulating layer and the second gate insulating layer; and
forming a source region and a drain region at surface portions of the substrate adjacent to the first gate insulating layer and the second gate insulating layer, respectively.

8. The method of claim 7, wherein the first gate insulating layer and the second gate insulating layer are formed on a low voltage region of the substrate configured for use at a first, relatively lower voltage.

9. The method of claim 8, further comprising forming a preliminary gate insulating layer on the low voltage region and a high voltage region of the substrate configured for use at a second, relatively higher voltage.

10. The method of claim 9, wherein the forming the first gate insulating layer and the second gate insulating layer comprises:
implanting fluorine ions into a region on which the second gate insulating layer will be formed; and
performing a thermal oxidation process so as to form the first gate insulating layer and the second gate insulating layer.

11. The method of claim 10, further comprising removing a portion of the preliminary gate insulating layer on the low voltage region configured for use at a first, relatively lower voltage before performing the thermal oxidation process.

12. The method of claim 11, wherein a thickness of the high voltage gate insulating layer is greater than a thickness of the second gate insulating layer, and wherein the high voltage gate insulating layer is formed on the high voltage region by the thermal oxidation process.

13. The method of claim 7, wherein the source region has a lightly doped drain (LDD) structure.

14. The method of claim 7, wherein the drain region has a double diffused drain (DDD) structure.

15. The method of claim 7, wherein the first gate insulating layer and the second gate insulating layer are formed on a high voltage region of the substrate configured for use at a second, relatively higher voltage.

16. The method of claim 15, wherein the forming the first gate insulating layer and the second gate insulating layer comprises:
implanting fluorine ions into a region on which the second gate insulating layer will be formed;
performing a first thermal oxidation process so as to form a first preliminary gate insulating layer and a second preliminary gate insulating layer having a thickness greater than a thickness of the first preliminary gate insulating layer; and
performing a second thermal oxidation process so as to form the first gate insulating layer and the second gate insulating layer.

17. The method of claim 16, further comprising removing a portion of the first preliminary gate insulating layer formed on a low voltage region of the substrate by the first thermal oxidation process before performing the second thermal oxidation process.

18. The method of claim 17, wherein a low voltage gate insulating layer having a thickness less than a thickness of the first gate insulating layer is formed on the low voltage region by the second thermal oxidation process.

19. The method of claim 17, further comprising implanting fluorine ions into a portion of the low voltage region before removing the portion of the first preliminary gate insulating layer.

20. The method of claim 19, wherein a third gate insulating layer and a fourth gate insulating layer having a thickness greater than a thickness of the third gate insulating layer are formed on the low voltage region by the second thermal oxidation process, and the fourth gate insulating layer is formed on the portion of the low voltage region and has a thickness thinner than the thickness of the first gate insulating layer.
